(19) United States
(12) Patent Application Publication
(10) Pub. No.: US 2013/0187180 A1
(43) Pub. Date: Jul. 25, 2013

(54) LIGHT EMITTING DIODE FOR PLANT GROWTH

(71) Applicant: Hsing Chen, HsinChu (TW)

(72) Inventor: Hsing Chen, HsinChu (TW)

(21) Appl. No.: 13/356,656

(22) Filed: Jan. 24, 2012

(51) Int. Cl. H01L 33/50

(52) U.S. Cl. 257/98; 257/E33.061

(57) ABSTRACT

The present invention is a lighting device for plant growth, it is composed of a blue LED chip as the light source with different colors of phosphor powders. The wave length of blue chip falls in the range of 440-460 nm which stimulates stoma opening to absorb carbon dioxide. By formulating the right recipe of phosphors, the emitted light will have the spectra very close to that of light necessary for plant photosynthesis. It has the combined functions of good plant photosynthesis, stoma opening stimulation and some photomorphogenesis in one single device. It is a very prominent invention of artificial lights for plant growth ever seen.

### BACKGROUND OF THE INVENTION

1. Field of the Invention

The present invention relates to a lighting device for plant growth, it is composed of a blue LED chip as the light source with different colors of phosphor powders, one of which must be red phosphor. The phosphors are mixed with silicone gel, and the mixture encapsulates the blue LED chip, this integrated body could emit light when applied with electricity. By formulating the phosphors, the emitted light will have the spectral very close to that of light necessary for plant photosynthesis. It is a very effective lighting source which could increase plant growth rates at lower energy cost than those artificial lights available in the market.

2. Description of the Prior Art

It is known that different light intensity, light spectra & lengths of light exposure time could result in different growths of plants. Photosynthesis is the most important part to the growth of plants. Accordingly it needs light with right spectra. The spectrum shown in FIG. 1 is the most efficient light for photosynthesis which is well known in agriculture literatures. Any artificial light has its spectrum closest to that shown in FIG. 1 possesses the highest efficiency of photosynthesis.

Artificial lights for plant growths have been widely used in agriculture and horticulture for higher productivity and off-season harvest. There are some types of light sources used for plant growth currently:

1. Fluorescent lamps: The fluorescent lamps used in plant growth have the advantage of energy-saving, but its life is short comparing with that of LED, the other shortcomings are low photosynthesis efficiency, its spectrum shown in FIG. 2 is deviated from that of the photosynthesis spectrum shown in FIG. 1, and the disposal of fluorescent lamps causes environment pollution.
2. High pressure sodium lamps: High pressure sodium lamps have the advantages of higher power available, larger illuminated area, but with shorter life comparing with that of LED. There are more shortcomings: Low photosynthesis efficiency, its spectrum shown in FIG. 3 is deviated from that of the photosynthesis spectrum shown in FIG. 1, and there is too much heat generated which obstructs plant growths.
3. A LED lighting module with red LED chips and blue LED chips inside, it has the advantages of energy saving, long life and low heat. However the photosynthesis efficiency is low, its spectrum shown in FIG. 4 is deviated from that of the photosynthesis spectrum shown in FIG. 1.

Carbon dioxide is a necessary constituent for photosynthesis for green plants. Carbon dioxide absorbed by plants through stomas on leaves, the absorption is controlled

by the size of opening slots of stomas. The blue light (440-460 nm) plays the role for controlling stomas opening. That's why most of the current market available LED lamps contain both red LED chips and blue LED chips (commonly with the ratio of 8:1). But the big problem is the spectrum has only two sharp peaks (shown in FIG. 4), the absence of the other wavelengths (e.g. >=700 nm) results in low photosynthesis efficiency and abnormal photomorphogenesis.

### SUMMARY OF THE INVENTION

The present invention is about a lighting device for plant growth, it provides spectra closely matching the photosynthesis spectrum, and enhances plants growth rates at lower cost.

Besides, the present invention with broad spectra (comparing the sharp peaks LED type) can be applied with different light intensity & lengths of light exposure time & varying temperatures which could affect the morphogenesis of plants. That could make the plant life cycles short and could delay or advance the natural harvest seasons for good market.

For the above-mentioned purposes, this invention is composed of a blue 440˜460 nm LED chip and phosphors. The LED chip could excite phosphors as well as play the role for controlling stoma openings on leaves to absorb carbon dioxide. Blue light 440-460 nm affects the opening and closing of stomas and the amount of carbon dioxide absorption accordingly. At least two different colors of phosphor powders are contained, one of which must be red phosphor. The phosphors are mixed with silicone gel, and the mixture encapsulates the blue LED chip, this integrated body could emit light when applied with electricity. By formulating the phosphors, the emitted light will have the spectral very close to that of light necessary for plant photosynthesis shown in FIG. 1. It is a prominent invention combining a stoma opening function with photosynthesis function in one LED lighting device.

The unit expressed in vertical axis in attached figures. is “relative intensity of the energy”. In fact, it should be “micro mole photon per square meter per second”. But due to that this is an emerging technology, there is no commercial instruments available to measure the photon flux intensity. Whereas the “relative intensity of the energy” is sufficient to some extent to manifest this invention comparing to that of the unit, “Lux” or “Lumen per square meter”, a human sensational factor for light.

### BRIEF DESCRIPTION OF THE DRAWINGS

FIG. 1 shows the most efficient spectrum for plant photosynthesis.

FIG. 2 shows the spectrum of a fluorescent lamp.

FIG. 3 shows the spectrum of a high-pressure sodium lamp.

FIG. 4 shows the spectrum of a LED lighting device containing red LED chips and blue LED chips.

FIG. 5 shows the structure of the present invention.

FIG. 6 shows the spectrum of the 1^{st} embodiment of this invention.

FIG. 7 shows the CIE chromaticity coordinates of FIG. 6.

FIG. 8 shows the spectrum of the 2^{nd} embodiment of this invention.

FIG. 9 shows the CIE chromaticity coordinates of FIG. 8

FIG. 10 shows the spectrum of the 3^{rd} embodiment of this invention.

FIG. 11 shows the CIE chromaticity coordinates of FIG. 10.

### DETAILED DESCRIPTION OF THE PREFERRED EMBODIMENT

All the embodiments mentioned here are referred to FIG. 5 for structure and constituents manifesting. The present invention is a lighting device for plant growth, it is composed of a blue LED chip 10 as the light source having the wavelength of 440-460 nm and at least two different colors of phosphor powders 12, one of which must be red phosphor. The phosphors 12 are mixed with silicone gel 14, and the mixture encapsulates the blue LED chip 10, this integrated body could emit light when applied with electricity.

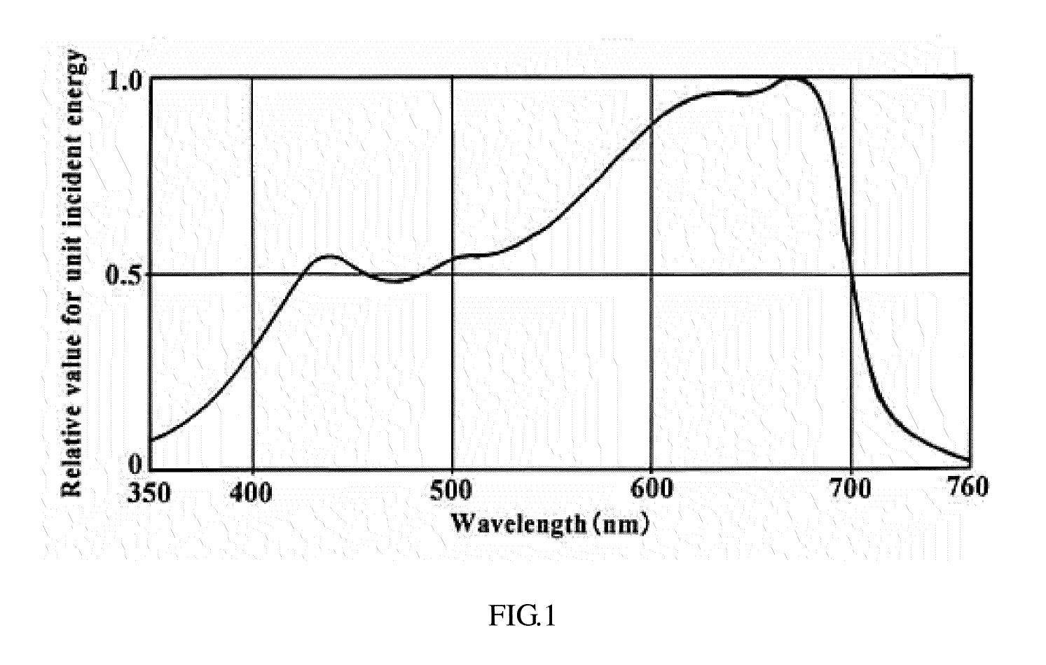

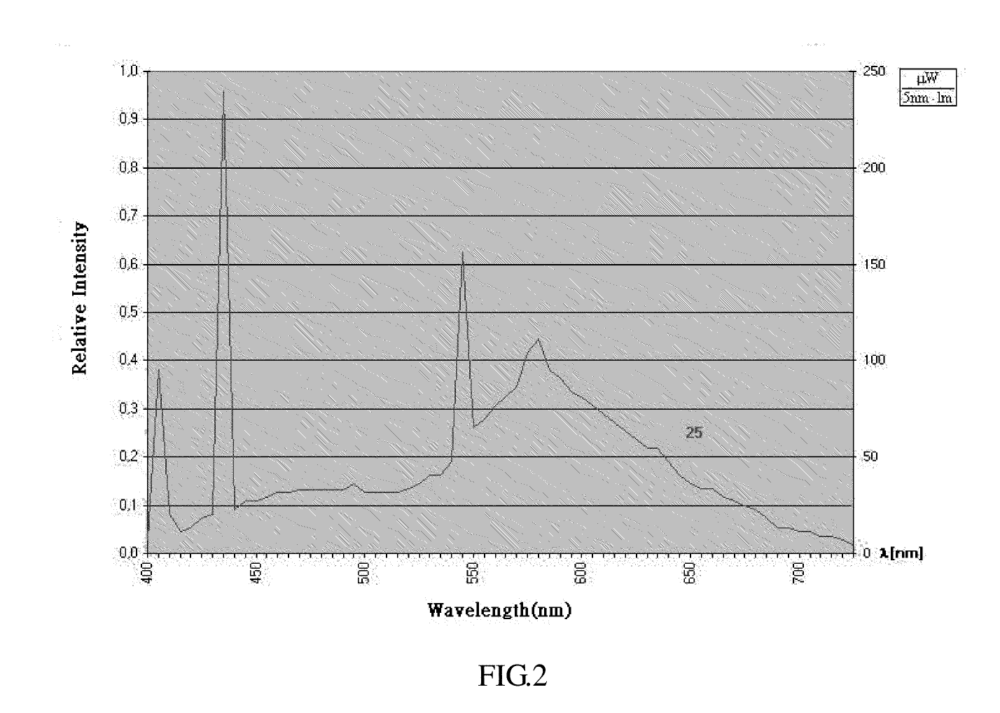

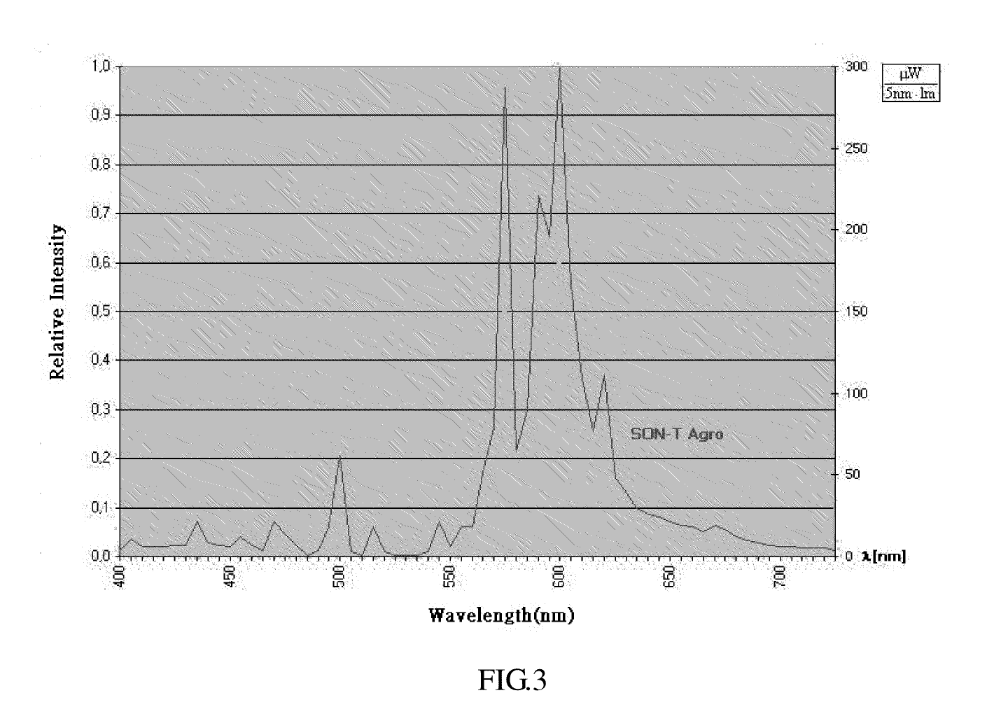

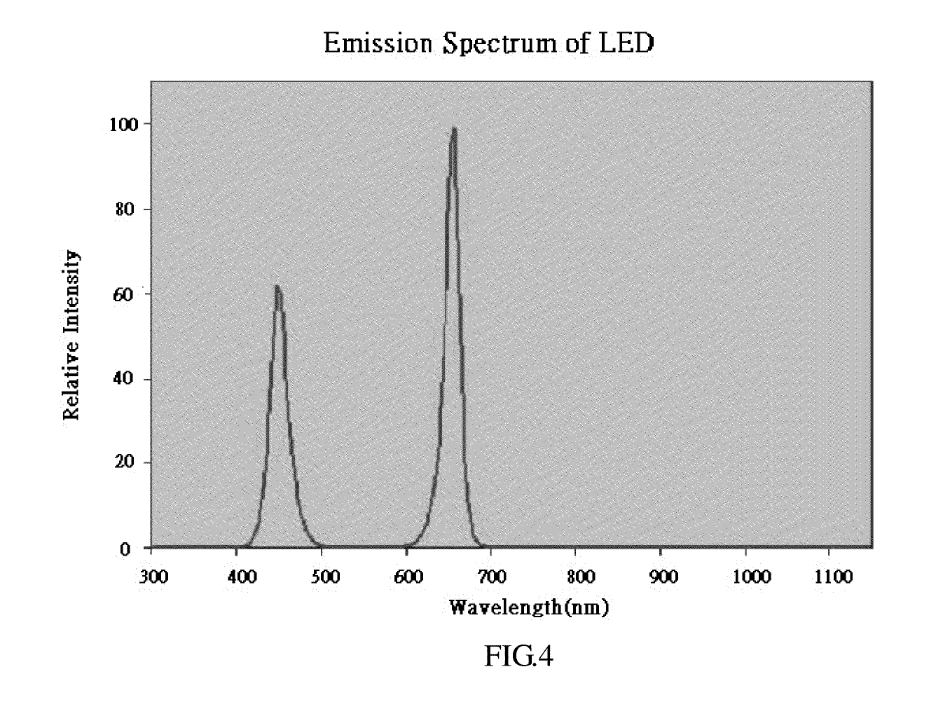

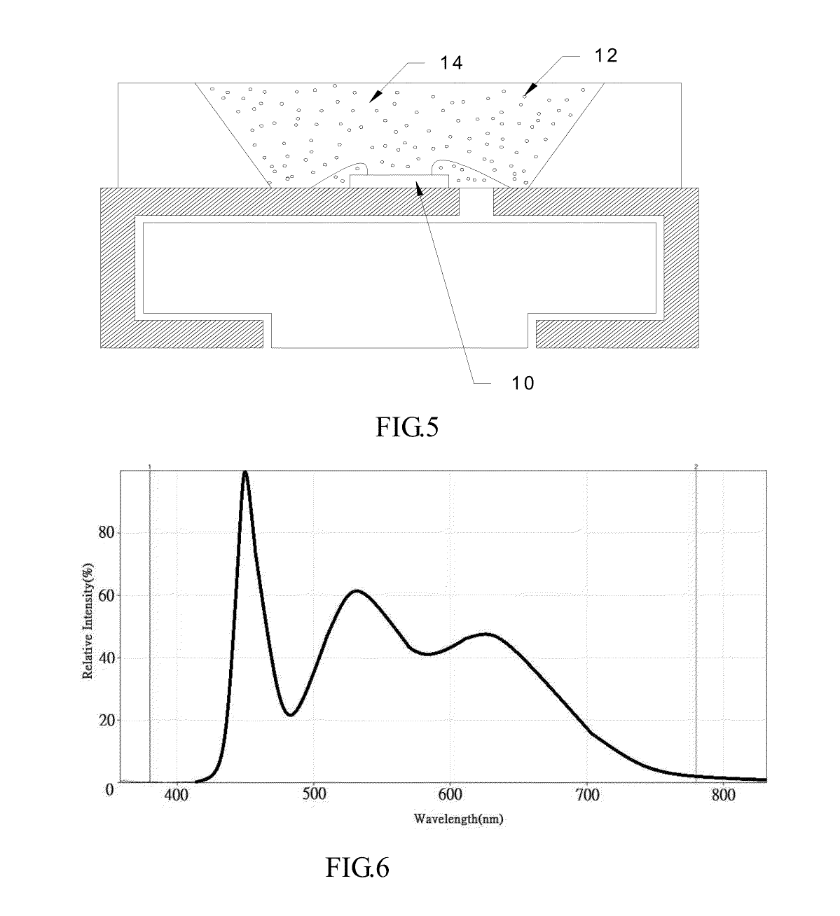

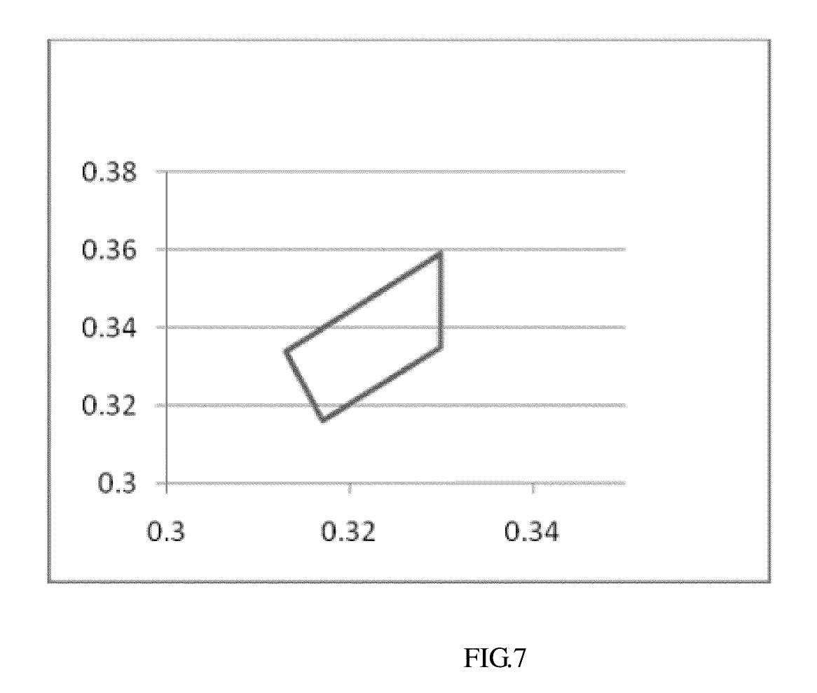

Embodiment 1, please refer to FIG. 6 and FIG. 7, wherein the phosphor powders 12 include a green phosphor, emits light with wavelength 515-540 nm, and a red phosphor emits light with wavelength 600-780 nm. And the green phosphor is a silicate with chemical formula [BaxSr(1−x)]2SiO4:Eu or a aluminate with chemical formula (Lu3Al5O12:Ce), the red phosphor is a nitride with chemical formula (CaAlSiN3:Eu, Ca2Si5N8:Eu) or a oxynitride with chemical formula (Ba3Si6O12:Eu), the mass ratio of green phosphor to red phosphor ratio is 12:88. The phosphors 12 are mixed with silicone gel 14, and the mixture encapsulates the blue LED chip 10, this integrated body could emit light when applied with electricity. it provides spectra closely matching the photosynthesis spectrum FIG. 1. The spectra when expressed in luminous scale their CIE chromaticity coordinates will fall in the range of X:0.31˜0.35, Y:0.31˜0.38.

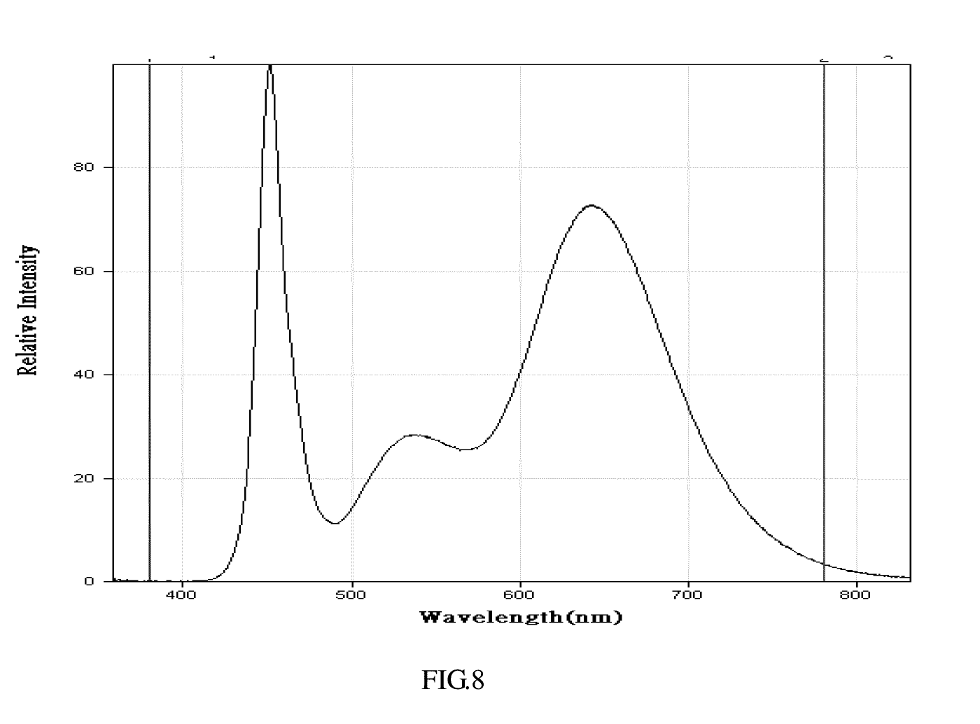

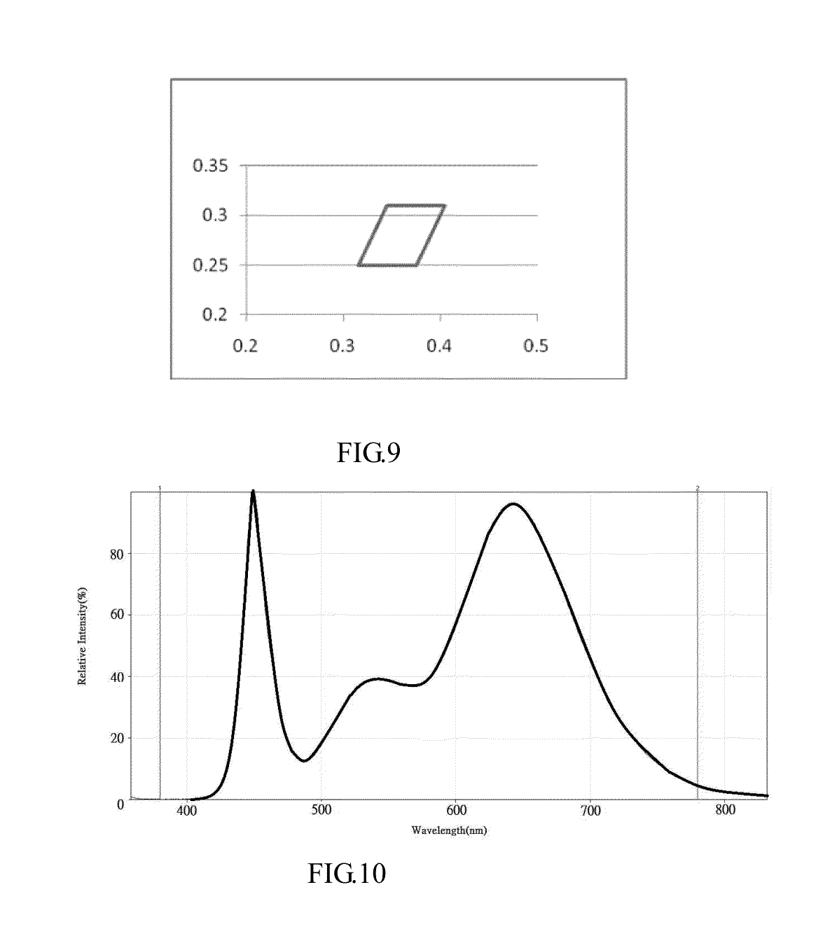

Embodiment 2, please refer to FIG. 8 and FIG. 9, wherein the phosphor powders 12 include a green phosphor, emits light with wavelength 515-540 nm, a yellow phosphor, emits light with wavelength 540˜570 nm and a red phosphor emits light with wavelength 600˜780 nm. And the green phosphor is a silicate with chemical formula [BaxSr(1−x)]2SiO4:Eu or a aluminate with chemical formula (Lu3Al5O12:Ce), the yellow phosphor is a silicate with chemical formula [BaxSr(1−x)]2SiO4:Eu, the red phosphor is a nitride with chemical formula (CaAlSiN3:Eu, Ca2Si5N8:Eu) or a oxynitride with chemical formula (Ba3Si6O12:Eu), the mass ratio of green phosphor to yellow phosphor to red phosphor ratio is 38:49:13. The phosphors 12 are mixed with silicone gel 14, and the mixture encapsulates the blue LED chip 10, this integrated body could emit light when applied with electricity. it provides spectra closely matching the photosynthesis spectrum FIG. 1. The spectra when expressed in luminous scale their CIE chromaticity coordinates will fall in the range of X:0.31˜0.46, Y:0.25˜0.36.

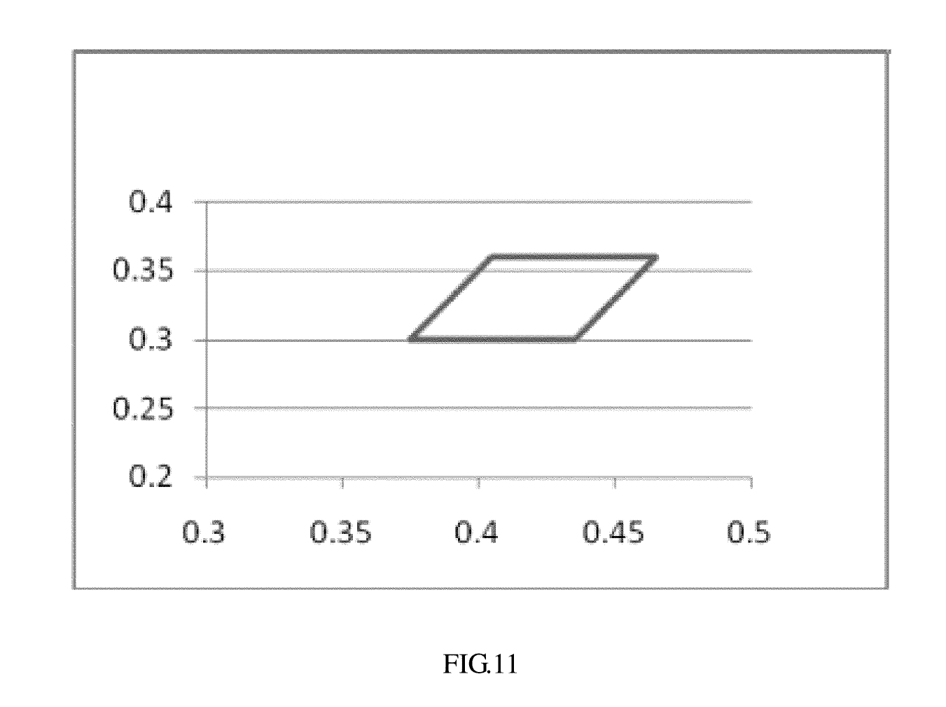

Embodiment 3, please refer to FIG. 10 and FIG. 11, wherein the phosphor powders 12 include a yellow phosphor, emits light with wavelength 540˜570 nm and a red phosphor emits light with wavelength 600˜780 nm. And the yellow phosphor is a silicate with chemical formula [BaxSr(1−x)]2SiO4:Eu, the red phosphor is a nitride with chemical formula (CaAlSiN3:Eu, Ca2Si5N8:Eu) or a oxynitride with chemical formula (Ba3Si6O12:Eu), the mass ratio of yellow phosphor to red phosphor ratio is 85:15. The phosphors 12 are mixed with silicone gel 14, and the mixture encapsulates the blue LED chip 10, this integrated body could emit light when applied with electricity, it provides spectra closely matching the photosynthesis spectrum FIG. 1. The spectra when expressed in luminous scale their CIE chromaticity coordinates will fall in the range of X:0.37˜0.46, Y:0.30˜0.36.

Those above-mentioned embodiments manifest this present invention about a lighting device for plant growth, providing spectra closely matching the photosynthesis spectrum, FIG. 1, and enhances plants growth rates at lower cost. It is composed of a blue LED chip as the light source with at least two different colors of phosphor powders, one of which must be red phosphor. The phosphors are mixed with silicone gel, and the mixture encapsulates the blue LED chip, this integrated body could emit light when applied with electricity. By formulating the phosphors, the emitted light will have the spectral very close to that of light necessary for plant photosynthesis.

Repeated experiments of the mentioned embodiments concluded that the spectra will have a good match with photosynthesis spectrum (FIG. 1) if their luminous scale CIE chromaticity coordinates fall in the range of X:0.31˜0.46, Y:0.25˜0.38. The present invention of lighting device provides out-standing plants growth rates at lower cost than those artificial lights available in the market. This invention comprehends a lighting device for plant growth, composed of a right blue LED chip as the light source with right recipes of phosphor powders. It has the combined functions of good plant photosynthesis, stoma opening stimulation and photomorphogenesis in one single device. It is a very prominent invention of artificial lights for plant growth ever seen.

While the invention has been described by the way of examples and in terms of preferred embodiments, it is to be understood that the invention is not limited to the disclosed embodiments. On the contrary, it is intended to cover various modifications. Therefore, the scope of the appended claims should be accorded the broadest interpretation so as to encompass all such modifications.

What is claimed is:

1. A lighting device for plant growth comprising
A blue LED chip having the wavelength of 440-460 nm;
At least two different colors of phosphor powders, one of which must be red phosphor.
The phosphors are mixed with silicone gel, and the mixture encapsulates the blue LED chip, this integrated body could emit light when applied with electricity. By formulating the phosphors, the emitted light will have the spectral very close to that of light necessary for plant photosynthesis.

2. The lighting device for plant growth according to claim 1, wherein the phosphor powders, one is a green phosphor, emits light with wavelength 515-540 nm, and the other is a red phosphor, emits light with wavelength 600˜780 nm.

3. The lighting device for plant growth according to claim 2, wherein the green phosphor is a silicate with chemical formula [BaxSr(1−x)]2SiO4:Eu or a aluminate with chemical formula (Lu3Al5O12:Ce), the red phosphor is a nitride with chemical formula (CaAlSiN3:Eu, Ca2Si5N8:Eu) or a oxynitride with chemical formula (Ba3Si6O12:Eu).

4. The lighting device for plant growth according to claim 2, wherein the mass ratio of green phosphor to red phosphor ratio is 12:88.

5. The lighting device for plant growth according to claim 2, wherein the spectra when expressed in luminous scale their CIE chromaticity coordinates will fall in the range of X:0.31˜0.35, Y:0.31˜0.38.

6. The lighting device for plant growth according to claim 1, wherein the phosphor powders, one is a green phosphor, emits light with wavelength 515-540 nm, the second one is a yellow phosphor, emits light with wavelength 540˜570 nm and the other is a red phosphor, emits light with wavelength 600˜780 nm.

7. The lighting device for plant growth according to claim 6, wherein the green phosphor is a silicate with chemical formula [BaxSr(1−x)]2SiO4:Eu or a aluminate with chemical formula (Lu3Al5O12:Ce), the yellow phosphor is a silicate with chemical formula [BaxSr(1−x)]2SiO4:Eu, the red phosphor is a nitride with chemical formula (CaAlSiN3:Eu, Ca2Si5N8:Eu) or an oxynitride with chemical formula (Ba3Si6O12:Eu).

8. The lighting device for plant growth according to claim 6, wherein the mass ratio of green phosphor to yellow phosphor to red phosphor ratio is 38:49:13.

9. The lighting device for plant growth according to claim 6, wherein the spectra when expressed in luminous scale their CIE chromaticity coordinates will fall in the range of X:0.31˜0.46, Y:0.25˜0.36.

10. The lighting device for plant growth according to claim 1, wherein the phosphor powders one is a yellow phosphor, emits light with wavelength 540˜570 nm, and the other is a red phosphor, emits light with wavelength 600˜780 nm.

11. The lighting device for plant growth according to claim 10, wherein the yellow phosphor is a silicate with chemical formula [BaxSr(1−x)]2SiO4:Eu, the red phosphor is a nitride with chemical formula (CaAlSiN3:Eu, Ca2Si5N8:Eu) or an oxynitride with chemical formula (Ba3Si6O12:Eu).

12. The lighting device for plant growth according to claim 10, wherein the mass ratio of yellow phosphor to red phosphor ratio is 85:15

13. The lighting device for plant growth according to claim 10, wherein the spectra when expressed in luminous scale their CIE chromaticity coordinates will fall in the range of X:0.37˜0.46, Y:0.30˜0.36.
